(19) United States
(12) Patent Application Publication
(10) Pub. No.: US 2025/0149399 A1
(43) Pub. Date: May 8, 2025

(54) POWER MODULE AND POWER CONVERSION APPARATUS

(71) Applicant: Mitsubishi Electric Corporation, Chiyoda-ku, Tokyo (JP)

(72) Inventors: Junji FUJINO, Tokyo (JP); Chika KAWAZOE, Tokyo (JP); Michio OGAWA, Tokyo (JP); Yuji IMOTO, Tokyo (JP); Fumio WADA, Tokyo (JP)

(73) Assignee: Mitsubishi Electric Corporation, Chiyoda-ku, Tokyo (JP)

(21) Appl. No.: 18/838,152

(22) PCT Filed: Mar. 17, 2023
(86) PCT No.: PCT/JP2023/010614

§ 371 Date: Aug. 13, 2024

(30) Foreign Application Priority Data
Apr. 4, 2022 (JP) 2022-062224

(51) Int. Cl. H01L 23/367; H01L 23/00; H01L 23/29; H01L 23/538; H01L 25/18; H02M 7/5387

(52) U.S. Cl. CPC H01L 23/3672; H01L 23/5383; H01L 24/48; H01L 25/18; H02M 7/5387; H01L 23/295; H01L 24/29; H01L 24/83; H01L 2224/29111; H01L 2224/29139; H01L 2224/29147; H01L 2224/48137; H01L 2224/48155; H01L 2224/48225; H01L 2224/83815; H01L 2924/3511; H01L 2924/3512

(57) ABSTRACT

An object is to provide a technique capable of suppressing a warpage of a heat radiation member caused by heat stress in a power module. A power module includes: a semiconductor element; a ceramic substrate including a mounting surface on which the semiconductor element is mounted; and a fin base bonded to a surface of the ceramic substrate on a side opposite to the mounting surface, wherein a bonding region in the ceramic substrate bonded to the fin base is a region corresponding to a portion on which the semiconductor element is mounted, and an area of the bonding region in the ceramic substrate bonded to the fin base is smaller than an area of the portion on which the semiconductor element is mounted.

### TECHNICAL FIELD

The present disclosure relates to a power module and a power conversion apparatus.

### BACKGROUND ART

A power module is mounted on every product such as an industrial apparatus, a home electrical appliance, and an information terminal, and high productivity is required in a power module. A high heat radiation property is required in a power module mounted on an electrical automobile, and a high degree of flatness is required to ensure fastening to a water-cooling jacket. Also required is a package form adoptable to SiC semiconductor which has a high possibility of becoming mainstream in the future since the SiC semiconductor has a high operation temperature and is excellent in efficiency.

The power module is becoming popular in every situation of power generation, power transmission, and power regeneration of electrical energy with increase of environmental problems. Large current and high voltage are handled in the power module, thus a ceramic substrate having a high insulation property and a high heat radiation property is used as an insulating substrate. However, aluminum nitride and silicon nitride, for example, as a material of a ceramic base material has a significantly small linear expansion coefficient compared with copper and aluminum used for a heat radiation member, for example. Thus, when these members are bonded, large heat stress occurs in a bonding position, and there is a problem that a warpage and a crack in a temperature cycle easily occur in the heat radiation member.

For example, proposed in Patent Document 1 is a structure of a power module in which a semiconductor element is mounted on a ceramic substrate, a circuit is formed by wire bonding, and a pin terminal is used as an external terminal.

### PRIOR ART DOCUMENTS

### Patent Document(s)

Patent Document 1: Japanese Patent No. 5978589

### SUMMARY

### Problem to be Solved by the Invention

However, in the technique described in Patent Document 1, a front surface conductive layer serving as a circuit pattern is provided on an upper surface of the ceramic substrate to mount the semiconductor element and the pin terminal, and a back surface conductive layer is provided on almost an entire lower surface of the ceramic substrate.

In a case of an in-vehicle power module mounted on an electrical automobile, for example, a size of an element exceeds 10 mm square, the number of elements is twelve in a case of 6in1 module, and a size of the ceramic substrate is large, that is 60 mm to 70 mm.

When the large ceramic substrate is bonded to a heat radiation member made of copper or aluminum, an excessive warpage occurs in the heat radiation member by reason that there is a large difference of linear expansion coefficient between the ceramic substrate and the heat radiation member. When a power module is water-cooled (liquid-cooled) using the heat radiation member, the power module needs to be generally fixed to a water-cooling jacket which is a metal rigid body. A warpage is suppressed to some extent by fastening with a screw, for example, however, the warpage needs to be further suppressed to evenly apply deformation pressure to an O-ring to obtain a watertight state.

Accordingly, an object of the present disclosure is to provide a technique capable of suppressing a warpage of a heat radiation member caused by heat stress in a power module.

### Means to Solve the Problem

A power module according to the present disclosure includes: a semiconductor element; an insulating substrate including a front surface conductive layer on which the semiconductor element is mounted and a back surface conductive layer on a side opposite to the front surface conductive layer; and a heat radiation member bonded to the back surface conductive layer, wherein a bonding region in the insulating substrate bonded to the heat radiation member is a region corresponding to a portion on which the semiconductor element is mounted, and an area of the front surface conductive layer is larger than an area of the back surface conductive layer.

### Effects of the Invention

According to the present disclosure, the area of the bonding region in the insulating substrate bonded to the heat radiation member is reduced, thus the warpage of the heat radiation member caused by heat stress can be suppressed.

These and other objects, features, aspects and advantages of the present disclosure will become more apparent from the following detailed description when taken in conjunction with the accompanying drawings.

### BRIEF DESCRIPTION OF DRAWINGS

FIG. 1 A cross-sectional view of a power module according to an embodiment 1.

FIG. 2 A top view illustrating a state where sealing resin is removed from the power module according to the embodiment 1.

FIG. 3 A bottom view of a ceramic substrate included in the power module according to the embodiment 1.

FIG. 4 A bottom view illustrating another example of the ceramic substrate included in the power module according to the embodiment 1.

FIG. 5 A bottom view illustrating still another example of the ceramic substrate included in the power module according to the embodiment 1.

FIGS. 6A to 6C A schematic diagram of a process of manufacturing the power module according to the embodiment 1.

FIG. 7 A cross-sectional view of a power module according to a modification example 1 of the embodiment 1.

FIG. 8 A cross-sectional view of a power module according to a modification example 2 of the embodiment 1.

FIG. 9 A top view illustrating a state where sealing resin is removed from the power module according to the modification example 2 of the embodiment 1.

FIG. 10 A bottom view of a ceramic substrate included in the power module according to the modification example 2 of the embodiment 1.

FIG. 11 A cross-sectional view of a power module according to an embodiment 2.

FIG. 12 A bottom view of a ceramic substrate included in the power module according to the embodiment 2.

FIG. 13 A cross-sectional view of a power module according to an embodiment 3.

FIG. 14 A bottom view of a ceramic substrate included in the power module according to the embodiment 3.

FIG. 15 A block diagram illustrating a configuration of a power conversion system to which a power conversion apparatus according to an embodiment 4 is applied.

### DESCRIPTION OF EMBODIMENT(S)

### Embodiment 1

### Configuration of Power Module

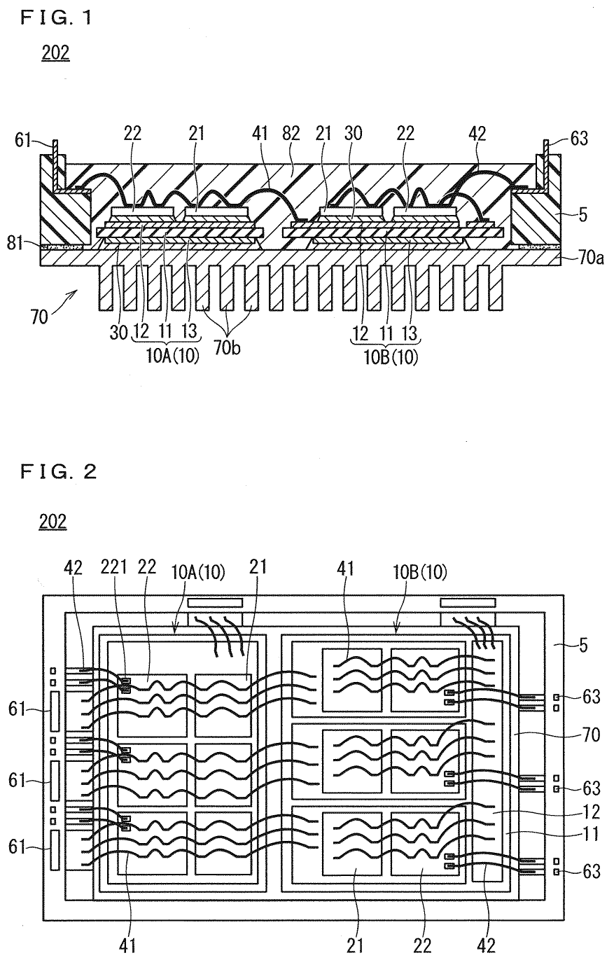

An embodiment 1 is described hereinafter using the diagrams. FIG. 1 is a cross-sectional view of a power module 202 according to the embodiment 1. FIG. 2 is a top view illustrating a state where sealing resin 82 is removed from the power module 202 according to the embodiment 1.

As illustrated in FIG. 1 and FIG. 2, the power module 202 is a 6in1 module, and includes six groups of semiconductor elements 21 and 22, two ceramic substrates 10A and 10B, a case 5, a plurality of external electrodes 61, a plurality of signal electrodes 63, the sealing resin 82 and a fin base 70. When two ceramic substrates 10A and 10B are not distinguished from each other, each of them is also simply referred to as the ceramic substrate 10. Herein, the ceramic substrate 10 corresponds to an insulating substrate, and the fin base 70 corresponds to a heat radiation member. The number of semiconductor elements 21 and 22 and the number of ceramic substrates 10 are not limited to six groups and two, respectively.

The case 5 is made of Polyphenylenesulfide (PPS) resin, and is formed into a rectangular frame-like shape in a top view. A size of the case 5 is 100 mm in width, 80 mm in depth, and 6 mm in thickness. The external electrode 61 and the signal electrode 63 are integrally formed with the case 5 by insert molding.

The fin base 70 is made of aluminum alloy, and includes a base part 70a and a plurality of pin parts 70b protruding to a lower side from the base part 70a. The base part 70a is formed into a rectangular shape in a top view. A size of the base part 70a is 100 mm in width, 80 mm in depth, and 3 mm in thickness. A size of each pin part 70b is 1.5 mm in diameter and 5 mm in length.

A peripheral edge part of an upper surface of the base part 70a is fixed to the case 5 by an adhesive agent 81. Nickel plating is applied to a region in the base part 70a except for the peripheral edge part of the upper surface thereof, and the region is bonded to the ceramic substrate 10 by a solder 30. The solder 30 is made of 96.5% tin, 3% silver, and 0.5% copper, and a melting point of the solder 30 is 217° C.

Each of two ceramic substrates 10 includes a base material 11, a front surface conductive layer 12, and a back surface conductive layer 13. The base material 11 is made of aluminum nitride, and a thickness of the base material 11 is 0.64 mm. The front surface conductive layer 12 is made of copper, and is provided on an upper surface of the base material 11. The front surface conductive layer 12 forms a mounting surface of the ceramic substrate 10 on which the semiconductor elements 21 and 22 are mounted. The back surface conductive layer 13 is made of copper, and is provided on a lower surface of the base material 11. The back surface conductive layer 13 forms a surface of the ceramic substrate 10 on a side opposite to the mounting surface thereof. Both the front surface conductive layer 12 and the back surface conductive layer 13 have a thickness of 0.8 mm, and formed by deposition by brazing.

The front surface conductive layer 12 of each of two ceramic substrates 10 includes a region on which the semiconductor elements 21 and 22 are mounted and a region for forming a circuit by a wire 41. Three groups of semiconductor elements 21 and 22 in six groups of semiconductor elements 21 and 22 constituting the 6in1 module are mounted on the front surface conductive layer 12 of each of two ceramic substrates 10 by the solder 30. The semiconductor element 21 is a diode made of silicon, and a size of the semiconductor element 21 is 13 mm in width, 10 mm in depth, and 0.2 mm in thickness. The semiconductor element 22 is an insulated gate bipolar transistor (IGBT) made of silicon, and a size thereof is 13 mm in width, 13 mm in depth, and 0.2 mm in thickness.

Two ceramic substrates 10A and 10B are described next. The ceramic substrate 10A (outline dimension 35 mm×65 mm) includes one front surface conductive layer 12 (outline dimension 31 mm×61 mm), and three groups of semiconductor elements 21 and 22 are mounted on one front surface conductive layer 12. The ceramic substrate 10B (outline dimension 45 mm×65 mm) includes four front surface conductive layers 12, and one group of semiconductor elements 21 and 22 is mounted on each of three large front surface conductive layers 12 (outline dimension 30 mm×19 mm).

A main terminal of each of the semiconductor elements 21 and 22 is connected to the external electrode 61 insert-formed in the case 5 by the wire 41 (0.4 in diameter) made of aluminum. A gate electrode 221 of the semiconductor element 22 and a signal electrode 63 insert-formed in the case 5 are wire-bonded by a wire 42 (0.15 in diameter) made of aluminum to form a circuit.

The sealing resin 82 is made of epoxy resin in which a silica filler is diffused.

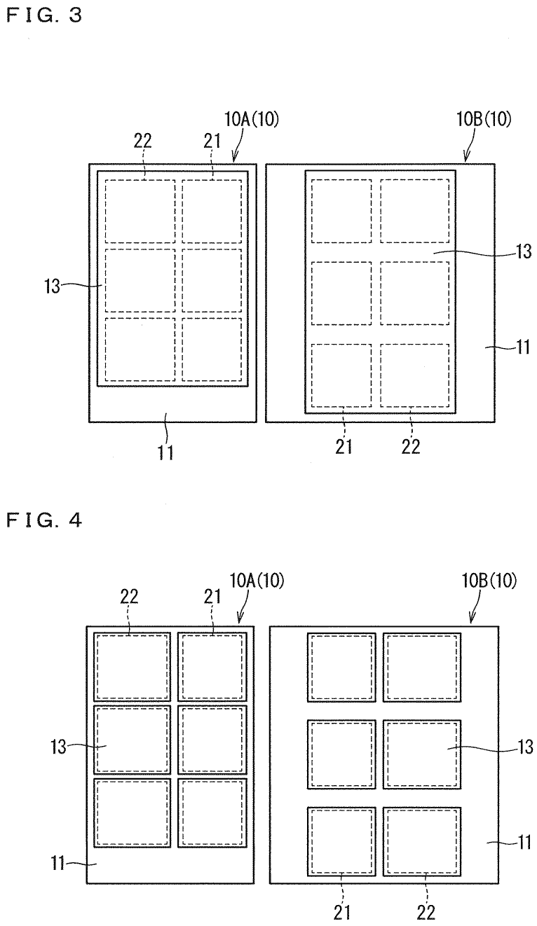

FIG. 3 is a bottom view of the ceramic substrates 10A and 10B included in the power module 202 according to the embodiment 1. As illustrated in FIG. 3, the back surface conductive layer 13 is formed in a region corresponding to a portion on which the semiconductor elements 21 and 22 are mounted. Specifically, the back surface conductive layer 13 is not divided but is integrally formed in a region corresponding to a whole portion on which three groups of semiconductor elements 21 and 22 are mounted, and is not formed in the other region. Accordingly, as illustrated in FIG. 1, there is no back surface conductive layer 13 in a region corresponding to a portion in which the wire 41 is directly bonded to the ceramic substrate 10, thus this region is not bonded to the base part 70a of the fin base 70. Thus, in this region, there is a gap between the base material 11 and the base part 70a of the fin base 70, and this gap is filled with the sealing resin 82. An outline dimension of the back surface conductive layer 13 included in the ceramic substrate 10A is 31 mm×55 mm, and an outline dimension of the back surface conductive layer 13 included in the ceramic substrate 10B is 31 mm×61 mm.

Herein, the region corresponding to the portion in the back surface conductive layer 13 on which the semiconductor elements 21 and 22 are mounted indicates a region in the back surface conductive layer 13 facing the semiconductor elements 21 and 22 via the base material 11 and the front surface conductive layer 12.

Described next is another example and still another example of the ceramic substrate 10. FIG. 4 is a bottom view illustrating another example of the ceramic substrates 10A and 10B included in the power module 202 according to the embodiment 1. As illustrated in FIG. 4, the back surface conductive layer 13 is divided into regions corresponding to portions on which the semiconductor elements 21 and 22 are mounted, respectively. That is to say, six back surface conductive layers 13 are provided to each ceramic substrate 10. Accordingly, an area of each back surface conductive layer 13 is reduced, thus an occurrence of shrinkage cavity which tends to occur in soldering with a large area can be suppressed.

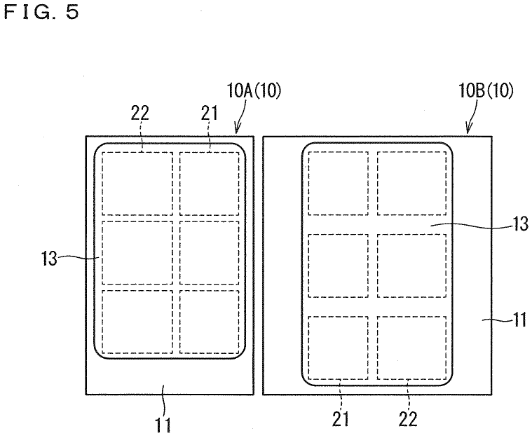

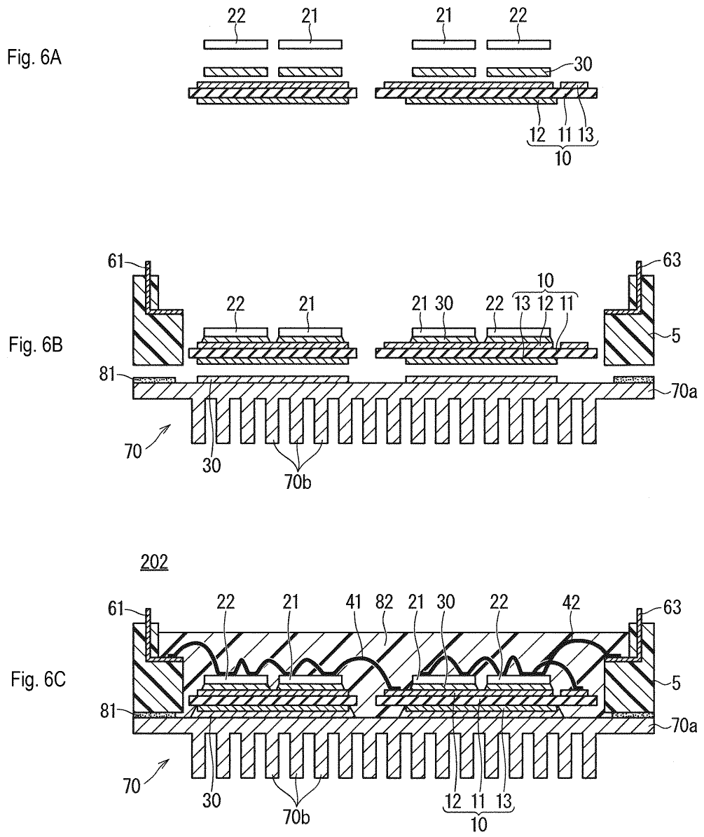

FIG. 5 is a bottom view illustrating still another example of the ceramic substrates 10A and 10B included in the power module 202 according to the embodiment 1. As illustrated in FIGS. 6A to 6C, the back surface conductive layer 13 is formed in a region corresponding to a portion on which three groups of semiconductor elements 21 and 22 are mounted. Each of the four corner parts of each back surface conductive layer 13 has a round-chamfered shape. Accordingly, occurrence of a crack in a temperature cycle which tends to occur in soldering with a large area can be suppressed.

### <Process of Manufacturing Power Module>

A process of manufacturing the power module 202 is described next. FIGS. 6A to 6C are schematic diagrams illustrating the process of manufacturing the power module 202 according to the embodiment 1.

As illustrated in FIG. 6A, the sheet-like solder 30 with a thickness of 0.2 mm is divided to have a predetermined dimension and is mounted on the front surface conductive layer 12 of the ceramic substrate 10, and the semiconductor elements 21 and 22 are positioned and disposed thereon. The semiconductor elements 21 and 22 on the front surface conductive layer 12 is heated in a reflow furnace, thus the semiconductor elements 21 and 22 are solder-bonded to the front surface conductive layer 12.

Next, as illustrated in FIG. 6B, the sheet-like solder 30 with a thickness of 0.4 mm and the ceramic substrate 10 are disposed in a region except for the peripheral edge part of the base part 70a of the fin base 70. The adhesive agent 81 is applied to the peripheral edge part of the base part 70a, and the case 5 is disposed thereon. This assembling body is heated in a reflow furnace to solder-bond the base part 70a to the ceramic substrate 10 and bond the base part 70a and the case 5 at the same time.

Finally, as illustrated in FIG. 6C, the semiconductor elements 21 and 22 and the external electrode 61 are bonded by the wire 41, and a signal electrode (not shown) of the semiconductor element 22 and the signal electrode 63 are bonded to each other by the wire 42. Subsequently, the sealing resin 82 is injected and thermally hardened in an oven, thus the power module 202 is manufactured.

### <Effect>

As described above, the power module 202 according to the embodiment 1 includes: the semiconductor elements 21 and 22; the ceramic substrate 10 including the mounting surface on which the semiconductor elements 21 and 22 are mounted; and the fin base 70 bonded to the surface of the ceramic substrate 10 on the side opposite to the mounting surface, wherein the bonding region in the ceramic substrate 10 bonded to the fin base 70 is the region corresponding to the portion on which the semiconductor elements 21 and 22 are mounted, and the area of the bonding region in the ceramic substrate 10 bonded to the fin base 70 is smaller than the area of the portion on which the semiconductor elements 21 and 22 are mounted.

Accordingly, when the area of the bonding region in the ceramic substrate 10 bonded to the fin base 70 is reduced, the warpage of the fin base 70 caused by the heat stress can be suppressed.

The ceramic substrate 10 includes the back surface conductive layer 13 forming the surface on the side opposite to the mounting surface, and the back surface conductive layer 13 is formed in the region corresponding to the portion on which the semiconductor elements 21 and 22 are mounted. The area of the back surface conductive layer 13 can be reduced, thus a weight of the power module 202 can be reduced. According to the above configuration, increase of durability and reduction of an energy consumption amount of the power module 202 can be achieved.

In any case of FIG. 3, FIG. 4, and FIG. 5, the area of the front surface conductive layer 12 of the ceramic substrate 10 is larger than that of the back surface conductive layer 13. That is to say, the area of a copper conductive layer having a large linear expansion coefficient is larger on the front surface of the ceramic substrate 10 than on the back surface thereof, however, the semiconductor elements 21 and 22 having a smaller linear expansion coefficient than the front surface conductive layer 12 are mounted on the front surface conductive layer 12, thus obtained is an effect that the warpage of the ceramic substrate 10 is offset and reduced.

Herein, three groups of semiconductor elements 21 and 22 are mounted on each of two ceramic substrates 10A and 10B. It is considered to be effective to reduce the number of semiconductor elements 21 and 22 mounted on each ceramic substrate 10 to one or two to reduce the outline dimension of the ceramic substrate 10 as much as possible from a viewpoint of temperature cycle performance and a warpage in each ceramic substrate 10. However, a region (frame region) large enough to locate only the base material 11 to some extent is necessary in the peripheral edge part of the ceramic substrate 10 to ensure an insulation property for the fin base 70, thus if the ceramic substrate 10 is divided too much, the frame region in the whole ceramic substrate 10 is increased, and the whole power module 202 gets large. Thus, it is considered to be effective to locate two ceramic substrates 10 to achieve the outline dimension so that three groups of semiconductor element 21 and 22 can be mounted to each ceramic substrate 10.

### Modification Example of Embodiment 1

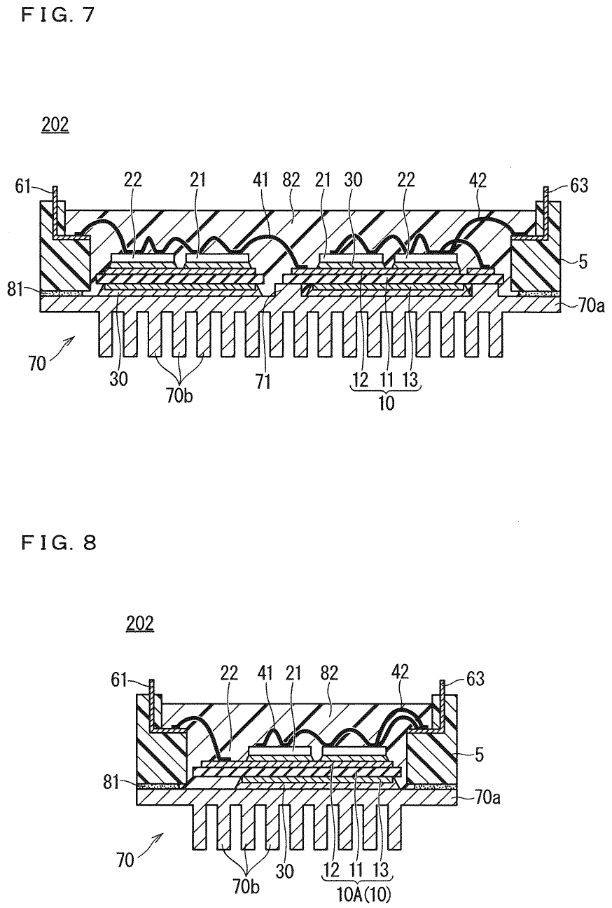

A modification example of the embodiment 1 is described next. FIG. 7 is a cross-sectional view of the power module 202 according to the modification example of the embodiment 1.

As illustrated in FIG. 7, provided to the fin base 70 is a convex part 71 having contact with a region to which the fin base 70 is not bonded in the surface of the ceramic substrate 10 on the side opposite to the mounting surface thereof. Specifically, the convex part 71 is provided in a position having contact with a region in which the back surface conductive layer 13 is not formed in the ceramic substrate 10.

A height of the convex part 71 is 1.0 mm. The sealing resin 82 has low heat conductivity, thus when the convex part 71 is provided, a thickness of the sealing resin 82 filling the gap between the base material 11 and the base part 70a of the fin base 70 can be reduced. Accordingly, Joule heat occurring in a bonding position between the wire 41 and the front surface conductive layer 12 can be easily radiated.

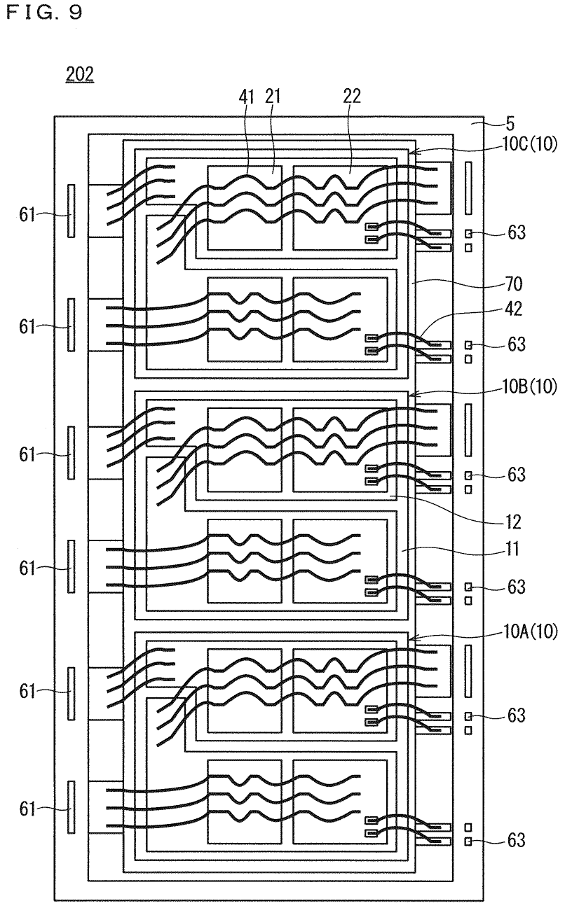

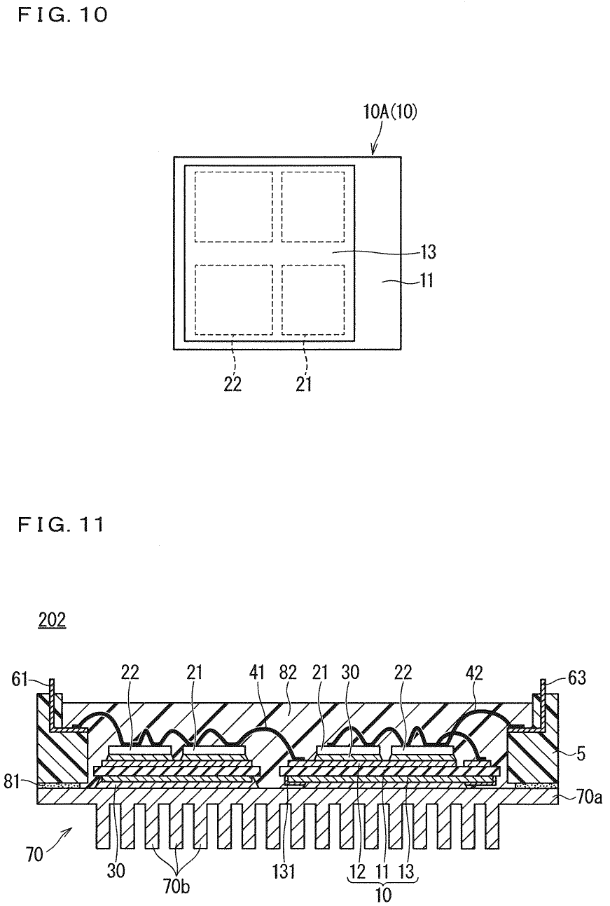

FIG. 8 is a cross-sectional view of the power module 202 according to a modification example 2 of the embodiment 1. FIG. 9 is a top view illustrating a state where sealing resin 82 is removed from the power module 202 according to the modification example 2 of the embodiment 1. FIG. 10 is a bottom view of the ceramic substrate 10A included in the power module 202 according to the modification example 2 of the embodiment 1. In the modification example 2 of the embodiment 1, the same reference numerals are assigned to the same constituent elements described in the embodiment 1, and the description thereof will be omitted.

As illustrated in FIG. 8 and FIG. 9, the power module 202 has a configuration that three 2in1 modules are arranged in the modification example 2 of the embodiment 1. The power module 202 includes six groups of semiconductor elements 21 and 22, three ceramic substrates 10A, 10B, and 10C, the case 5, the plurality of external electrodes 61, the plurality of signal electrodes 63, the sealing resin 82, and the fin base 70. When three ceramic substrates 10A, 10B, and 10C are not distinguished from each other, each of them is also simply referred to as the ceramic substrate 10.

The case 5 has a size different from that in the embodiment 1. The size of the case 5 is 70 mm in width, 120 mm in depth, and 6 mm in thickness.

In the fin base 70, the base part 70a has a size different from that in the embodiment 1. The size of the base part 70a is 70 mm in width, 120 mm in depth, and 3 mm in thickness.

Each of three ceramic substrates 10 has two front surface conductive layers 12 (outline dimension 41 mm×32 mm). Two groups of semiconductor elements 21 and 22 are mounted on each of two front surface conductive layers 12 in three ceramic substrates 10.

As illustrated in FIG. 10, the back surface conductive layer 13 (outline dimension 32 mm×32 mm) is formed in a region corresponding to a portion on which the semiconductor elements 21 and 22 are mounted. Specifically, the back surface conductive layer 13 is not divided but is integrally formed in a region corresponding to a whole portion on which two groups of semiconductor elements 21 and 22 are mounted, and is not formed in the other region. Accordingly, as illustrated in FIG. 10, there is no back surface conductive layer 13 in a region corresponding to a portion in which the wire 41 is directly bonded to the ceramic substrate 10, thus this region is not bonded to the base part 70a of the fin base 70. Thus, in this region, there is a gap between the base material 11 and the base part 70a of the fin base 70, and this gap is filled with the sealing resin 82. The configuration of the modification example 2 of the embodiment 1 can also be adopted to the modification example 1 of the embodiment 1 and the embodiments 2 and 3 described hereinafter.

Herein, two groups of semiconductor elements 21 and 22 are mounted on each of three ceramic substrates 10A, 10B, and 10C. It is considered to be effective to reduce the number of semiconductor elements 21 and 22 mounted on each ceramic substrate 10 to one or two to reduce the outline dimension of the ceramic substrate 10 as much as possible from a viewpoint of temperature cycle performance and a warpage in each ceramic substrate 10. However, a region (frame region) large enough to locate only the base material 11 to some extent is necessary in the peripheral edge part of the ceramic substrate 10 to ensure an insulation property for the fin base 70, thus when the ceramic substrate 10 is divided too much, the frame region in the whole ceramic substrate 10 is increased, and the whole power module 202 gets large. Thus, it is considered to be effective to locate three ceramic substrates 10 to achieve the outline dimension so that two groups of semiconductor element 21 and 22 can be mounted to each ceramic substrate 10.

### Embodiment 2

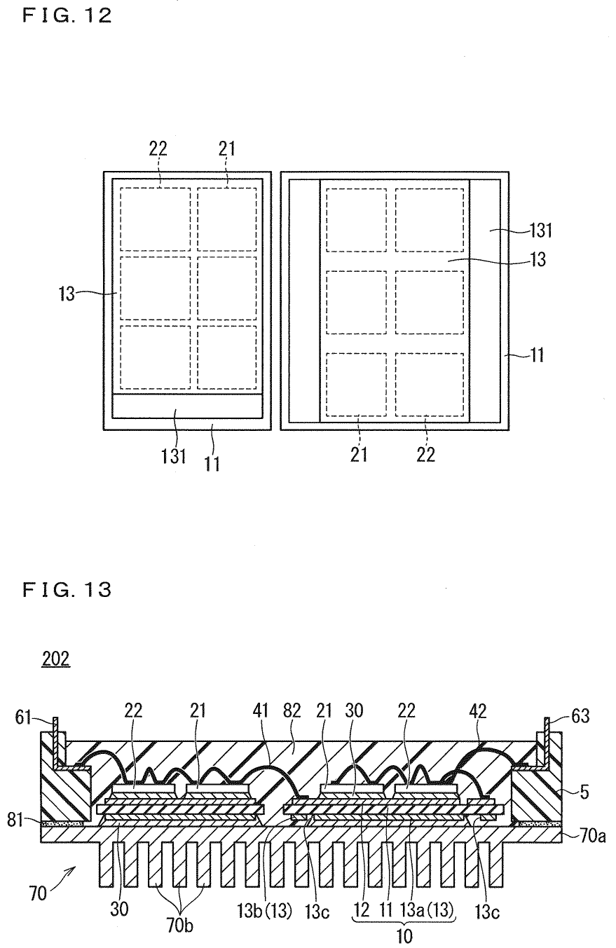

The power module 202 according to an embodiment 2 is described next. FIG. 11 is a cross-sectional view of the power module 202 according to the embodiment 2. FIG. 12 is a bottom view of the ceramic substrate 10 included in the power module 202 according to the embodiment 2. In the embodiment 2, the same reference numerals are assigned to the same constituent elements described in the embodiment 1, and the description thereof will be omitted.

As illustrated in FIG. 11 and FIG. 12, the back surface conductive layer 13 is provided to the whole back surface of the base material 11. A region in the back surface conductive layer 13 corresponding to a portion on which the semiconductor elements 21 and 22 are mounted is bonded to the base part 70a of the fin base 70, and a solder resist 131 made of UV curing resin is formed in the other region so as not to be bonded to the fin base 70. The solder resist 131 is soldered to a region in the back surface conductive layer 13 other than the region corresponding to the portion on which the semiconductor elements 21 and 22 are mounted.

As described above, in the power module 202 according to the embodiment 2, the ceramic substrate 10 includes the back surface conductive layer 13 forming the surface on the side opposite to the mounting surface, and the solder resist 131 is formed in the region in the back surface conductive layer 13 other than the region corresponding to the portion on which the semiconductor elements 21 and 22 are mounted so that the region is not bonded to the fin base 70.

Accordingly, the region in the back surface conductive layer 13 other than the region corresponding to the portion on which the semiconductor elements 21 and 22 are mounted is not bonded to the base part 70a of the fin base 70. When the area of the bonding area in the ceramic substrate 10 bonded to the fin base 70 is reduced, the warpage of the fin base 70 caused by the heat stress can be suppressed.

The convex part 71 in the modification example of the embodiment 1 may be provided to have contact with the region in which the solder resist 131 is formed in the ceramic substrate 10. Also in this case, the heat radiation property of Joule heat occurring in the bonding position between the wire 41 and the front surface conductive layer 12 can be improved.

### Embodiment 3

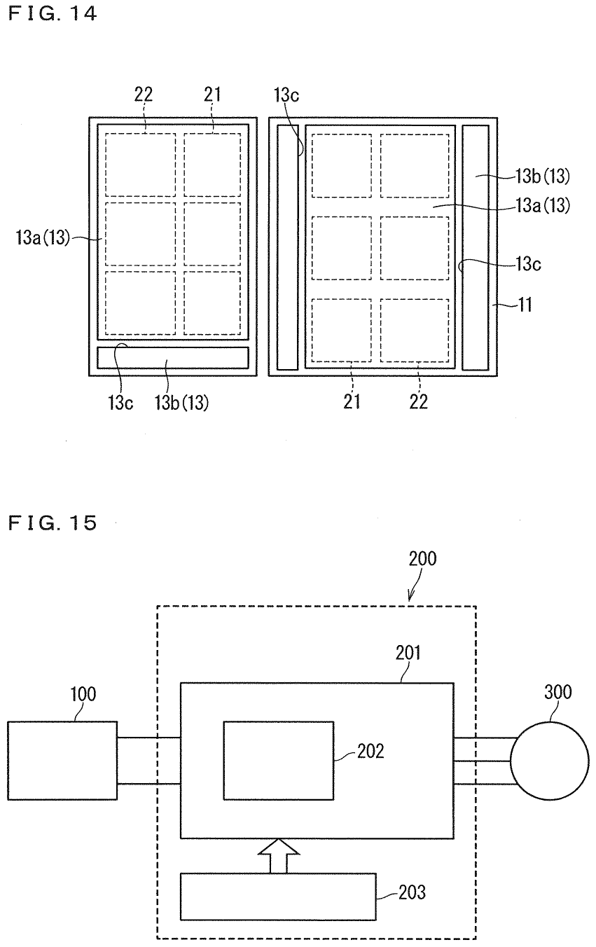

The power module 202 according to an embodiment 3 is described next. FIG. 13 is a cross-sectional view of the power module 202 according to the embodiment 3. FIG. 14 is a bottom view of the ceramic substrate 10 included in the power module 202 according to the embodiment 3. In the embodiment 3, the same reference numerals are assigned to the same constituent elements described in the embodiments 1 and 2, and the description thereof will be omitted.

As illustrated in FIG. 13 and FIG. 14, in the embodiment 3, the back surface conductive layer 13 is divided into a first region 13a as a region corresponding to a portion on which the semiconductor elements 21 and 22 are mounted and a second region 13b as the other region by a slit 13c. In the back surface conductive layer 13, the first region 13a is bonded to the base part 70a of the fin base 70, and the second region 13b is not bonded to the base part 70a.

As described above, in the power module according to the embodiment 3, the ceramic substrate 10 includes the back surface conductive layer 13 forming the surface on the side opposite to the mounting surface, and the back surface conductive layer 13 is divided into the first region 13a as the region corresponding to a portion on which the semiconductor elements 21 and 22 are mounted and the second region 13b as the other region by the slit 13c.

Accordingly, a difference of area between the front surface conductive layer 12 and the back surface conductive layer 13 is reduced, and the bonding area in the ceramic substrate 10 bonded to the fin base 70 can be reduced without an additional process such as a case of forming the solder resist 131.

The convex part 71 in the modification example of the embodiment 1 may be provided to have contact with the second region 13b. Also in this case, the heat radiation property of Joule heat occurring in the bonding position between the wire 41 and the front surface conductive layer 12 can be improved.

### Modification Example of Embodiments 1 to 3

In the above description, the base material 11 is made of aluminum nitride, however, a similar effect is obtained even when the base material 11 is made of silicon nitride or alumina. In the above description, the front surface conductive layer 12 and the back surface conductive layer 13 are made of copper, however, a similar effect is obtained even when they are made of aluminum by reforming surfaces thereof to be solder-wetted by nickel plating, for example.

In the above description, the fin base 70 is made of aluminum alloy, however, a similar effect is obtained even when the fin base 70 is made of copper or copper alloy. In the above description, the semiconductor elements 21 and 22 are made of silicon, however, a similar effect is obtained even when they are wide bandgap semiconductor such as silicon carbide and gallium nitride.

In the above description, the solder 30 is made of 96.5% tin, 3% silver, and 0.5% copper, and a melting point of the solder 30 is 217° C., however, a similar effect is obtained even when the solder 30 is made of 99.3% tin and 0.7% copper, and a melting point is 224° C., or when the solder 30 is made of 95% tin and 5% antimony, and a melting point is 240° C.

A similar effect is obtained even when the solder 30 is partially replaced with a bonding material other than the solder such as a silver epoxy adhesive agent, a silver sintering material, or a brazing material.

In the above description, the wires 41 and 42 are made of aluminum, however, a similar effect is obtained even when they are made of copper or aluminum alloy containing a slight amount of additive such as iron.

A similar effect is obtained by performing soldering on the upper surfaces of the semiconductor elements 21 and 22 using a copper frame to form the circuit in place of forming the circuit by wire bonding using the wires 41 and 42.

In the above description, the case 5 is made of PPS, it is also possible to improve heat resistance by replacing the material of the case 5 with liquid crystal polymer (LCP).

In the above description, the external electrode 61 and the signal electrode 63 are the copper frames, however, a similar effect is obtained even when nickel plating is appropriately applied thereon or they are replaced with copper alloy frames or nickel-plating aluminum frames.

In the above description, the sealing resin 82 is made of epoxy resin in which a silica filler is diffused, however, a filler such as alumina may be diffused in place of the silica filler, or a similar effect is obtained even when the sealing resin 82 is made of epoxy resin in which silicone resin is mixed. A similar effect is obtained even when the sealing resin 82 is made of only silicone resin.

### Embodiment 4

Applied in the present embodiment is the power module 202 according to the embodiments 1 to 3 described above to a power conversion apparatus. Application of the power module 202 according to the embodiments 1 to 3 is not limited to a specific power conversion apparatus, however, described hereinafter as an embodiment 4 is a case of applying the power module 202 according to the embodiments 1 to 3 to a three-phase inverter.

FIG. 15 is a block diagram illustrating a configuration of a power conversion system to which a power conversion apparatus according to the embodiment 4 is applied.

A power conversion system illustrated in FIG. 15 includes a power source 100, a power conversion apparatus 200, and a load 300. The power source 100 is a direct current power source, and supplies a direct current power to the power conversion apparatus 200. The power source 100 can be made up of various components, thus can be made up of a direct current system, a solar battery, or a storage battery, for example, and may also be made up of a rectification circuit connected to an alternating current system or an AC/DC converter. The power source 100 may also be made up of a DC/DC converter converting a direct current power being outputted from a direct current system into a predetermined power.

The power conversion apparatus 200 is a three-phase inverter connected between the power source 100 and the load 300, converts a direct current power supplied from the power source 100 into an alternating current power, and supplies the alternating current power to the load 300. As illustrated in FIG. 15, the power conversion apparatus 200 includes a main conversion circuit 201 converting a direct current power into an alternating current power and outputting the alternating current power and a control circuit 203 outputting a control signal for controlling the main conversion circuit 201 to the main conversion circuit 201.

The load 300 is a three-phase electrical motor driven by the alternating current power supplied from the power conversion apparatus 200. The load 300 is not for a specific purpose of usage, but is an electrical motor mounted on various types of electrical apparatuses, thus is used as an electrical motor for a hybrid automobile, an electrical automobile, a railroad vehicle, an elevator, or an air-conditioning machine, for example.

Details of the power conversion apparatus 200 are described hereinafter. The main conversion circuit 201 includes a switching element (not shown) and a reflux diode (not shown), and when the switching element is switched, the main conversion circuit 201 converts the direct current power supplied from the power source 100 into the alternating current power, and supplies the alternating current power to the load 300. Examples of a specific circuit configuration of the main conversion circuit 201 include various configurations, however, the main conversion circuit 201 according to the present embodiment is a three-phase full-bridge circuit with two levels, and can be made up of six switching elements and six reflux diodes antiparallelly connected to each switching element. At least one of each switching element and each reflux diode of the main conversion circuit 201 is made up of the power module 202 corresponding to any one of the embodiments 1 to 3 described above. Six switching elements are connected two by two in series to constitute upper and lower arms, and each pair of the upper and lower arms constitutes each phase (U phase, V phase, and W phase) of a full-bridge circuit. Output terminals of the pair of the upper and lower arms, that is to say, three output terminals of the main conversion circuit 201 are connected to the load 300.

The main conversion circuit 201 includes a drive circuit (not shown) driving each switching element, however, the drive circuit may be built in the power module 202, or also applicable is a configuration that the drive circuit is provided separately from the power module 202. The drive circuit generates a drive signal for driving a switching element of the main conversion circuit 201, and supplies the drive signal to a control electrode of the switching element of the main conversion circuit 201. Specifically, the drive circuit outputs a drive signal for making the switching element enter an ON state and a drive signal for making the switching element enter an OFF state to a control electrode of each switching element in accordance with a control signal from the control circuit 203 describe hereinafter. When the switching element is kept in the ON state, the drive signal is a voltage signal (ON signal) larger than a threshold voltage of the switching element, and when the switching element is kept in the OFF state, the drive signal is a voltage signal (OFF signal) smaller than the threshold voltage of the switching element.

The control circuit 203 controls the switching element of the main conversion circuit 201 so that a desired electrical power is supplied to the load 300. Specifically, the control circuit 203 calculates a time (on time) at which each switching element of the main conversion circuit 201 should enter the ON state based on the electrical power to be supplied to the load 300. For example, the control circuit 203 can control the main conversion circuit 201 by PWM control modulating the on time of the switching element in accordance with the voltage to be outputted. Then, the control circuit 203 outputs to a control command (control signal) to the drive circuit so that the ON signal is outputted to the switching element which should enter the ON state and the OFF signal is outputted to the switching element which should enter the OFF state at each point of time. The drive circuit outputs the ON signal or the OFF signal as the drive signal to the control electrode of each switching element in accordance with the control signal.

In the power conversion apparatus according to the present embodiment, the power module 202 according to the embodiments 1 to 3 is applied as the switching element and the reflux diode of the main conversion circuit 201, thus reduction of weight, increase of durability, and reduction of an energy consumption amount can be achieved.

Described in the present embodiment is the example of applying the power module 202 according to the embodiments 1 to 3 to three-phase inverter with two levels. However, the power module 202 according to the embodiments 1 to 3 is not limited thereto, but can be applied to various power conversion apparatuses. In the present embodiment, the power conversion apparatus with two levels is applied, however, a power conversion apparatus with three or multi levels may be applied, or the power module 202 according to the embodiments 1 to 3 may be applied to a single-phase inverter when the electrical power is supplied to a single-phase load. When the electrical power is supplied to a direct current load, for example, the power module 202 according to the embodiments 1 to 3 can be applied to a DC/DC converter or an AC/DC converter.

The power conversion apparatus to which the power module 202 according to the embodiments 1 to 3 is applied can be used not only in the case where the load described above is the electrical motor but can be used as a power source apparatus of an electrical discharge machine, a laser beam machine, an induction heat cooking machine, or a wireless power supply system, and further can also be used as a power conditioner of a solar power system or an electricity storage system, for example.

Although the present disclosure is described in detail, the foregoing description is in all aspects illustrative and does not restrict the disclosure. It is therefore understood that numerous modification examples can be devised.

Each embodiment can be arbitrarily combined, or each embodiment can be appropriately modified or omitted.

The aspects of the present disclosure are collectively described hereinafter as appendixes.

### (Appendix 1)

A power module, comprising:
a semiconductor element;
an insulating substrate including a front surface conductive layer on which the semiconductor element is mounted and a back surface conductive layer on a side opposite to the front surface conductive layer; and
a heat radiation member bonded to the back surface conductive layer, wherein
a bonding region in the insulating substrate bonded to the heat radiation member is a region corresponding to a portion on which the semiconductor element is mounted, and
an area of the front surface conductive layer is larger than an area of the back surface conductive layer.

### (Appendix 2)

The power module according to Appendix 1, wherein
the insulating substrate includes a plurality of insulating substrates,
the semiconductor element includes a plurality of semiconductor elements,
the plurality of semiconductor elements are six groups of transistors and diodes, and
two or three groups of transistors and diodes in the six groups of transistors and diodes are mounted on each of the insulating substrates.

### (Appendix 3)

The power module according to Appendix 1, wherein
the back surface conductive layer is formed in a region corresponding to a portion on which the semiconductor element is mounted.

### (Appendix 4)

The power module according to Appendix 1, wherein
a solder resist is formed in a region other than the region corresponding to the portion on which the semiconductor element is mounted in the back surface conductive layer so as not to be bonded to the heat radiation member.

### (Appendix 5)

The power module according to Appendix 1, wherein
the back surface conductive layer is divided into the region corresponding to the portion on which the semiconductor element is mounted and another region by a slit.

### (Appendix 6)

The power module according to Appendix 1, wherein
provided to the heat radiation member is a convex part having contact with a region in which the heat radiation member is not bonded in the surface of the insulating substrate on the side opposite to the front surface conductive layer.

### (Appendix 7)

A power conversion apparatus, comprising:
a main conversion circuit including the power module according to Appendix 1, converting an electrical power which has been inputted, and outputting the electrical power; and
a control circuit outputting a control signal for controlling the main conversion circuit to the main conversion circuit.

### EXPLANATION OF REFERENCE SIGNS

10, 10A, 10B, 10C ceramic substrate, 13 back surface conductive layer, 13a first region, 13b second region, 13c slit, 21, 22, semiconductor element, 70 fin base, 71 convex part, 131 solder resist, 200 power conversion apparatus, 201 main conversion circuit, 202 power module, 203 control circuit.

1. A power module, comprising:
a semiconductor element;
an insulating substrate including a front surface conductive layer on which the semiconductor element is mounted and a back surface conductive layer on a side opposite to the front surface conductive layer; and
a heat radiation member bonded to the back surface conductive layer, wherein
a bonding region in the insulating substrate bonded to the heat radiation member is a region corresponding to a portion on which the semiconductor element is mounted, and
an area of the front surface conductive layer is larger than an area of the back surface conductive layer.

2. The power module according to claim 1, wherein
the insulating substrate includes a plurality of insulating substrates,
the semiconductor element includes a plurality of semiconductor elements,
the plurality of semiconductor elements are six groups of transistors and diodes, and
two or three groups of transistors and diodes in the six groups of transistors and diodes are mounted on each of the insulating substrates.

3. The power module according to claim 1, wherein
the back surface conductive layer is formed in a region corresponding to a portion on which the semiconductor element is mounted.

4. The power module according to claim 1, wherein
a solder resist is formed in a region other than the region corresponding to the portion on which the semiconductor element is mounted in the back surface conductive layer so as not to be bonded to the heat radiation member.

5. The power module according to claim 1, wherein
the back surface conductive layer is divided into the region corresponding to the portion on which the semiconductor element is mounted and another region by a slit.

6. The power module according to claim 1, wherein
provided to the heat radiation member is a convex part having contact with a region in which the heat radiation member is not bonded in the surface of the insulating substrate on the side opposite to the front surface conductive layer.

7. A power conversion apparatus, comprising:
a main conversion circuit including the power module according to claim 1, converting an electrical power which has been inputted, and outputting the electrical power; and
a control circuit outputting a control signal for controlling the main conversion circuit to the main conversion circuit.
